(19) United States
(12) Patent Application Publication
(10) Pub. No.: US 2003/0143776 A1
(43) Pub. Date: Jul. 31, 2003

(54) Method of manufacturing an encapsulated integrated circuit package

(76) Inventors: Serafin Pedron JR., Manteca, CA (US); Neil Robert McLellan, Mid Levels (HK); Chun Ho Fan, Sham Tseng (HK); Luk Chung Ho Jerro, Hong Kong (HK); Lin Tsui Yee, Hong Kong (HK)

Correspondence Address: Christopher J. Gaspar, Esq., Milbank, Tweed, Hadley & McCloy LLP, One Chase Manhattan Plaza, New York, NY, 10005, US

(21) Appl. No.: 10/062,896

(22) Filed: Jan. 31, 2002

(51) Int. Cl. H01L 21/44; H01L 23/495; H01L 21/50

(52) U.S. Cl. 438/106; 438/111; 438/112; 438/118

(57) ABSTRACT

The present invention relates to a method of manufacturing an integrated circuit package, including providing a lead frame without a die attachment pad, the lead frame having a ridge portion protruding from a base portion, the ridge portion having an upper surface and defining an upper portion of a cavity, the base portion having a lead and a lower surface, attaching an adhesive strip to at least the lower surface of the base portion to seal a bottom portion of the cavity, encapsulating the cavity such that at least a portion of the upper surface of the ridge portion of the lead frame and at least a portion of the lower surface of the base portion are exposed, and removing the adhesive strip.

### FIELD OF THE INVENTION

The present invention relates to integrated circuit packaging technology, and more particularly, to processes for making encapsulated integrated circuit packages.

### BACKGROUND OF THE INVENTION

One way semiconductor devices have been packaged is by partial or complete encapsulation within a plastic or resinous material. Various shapes and sizes of such semiconductor packages exist. For example, U.S. Pat. No. 6,229,200 to Mclellan, entitled “Saw-Singulated Leadless Plastic Chip Carrier,” discloses a chip carrier having an encapsulation encapsulating a semiconductor die. In some situations, it may be desirable to create a semiconductor package of such a size that two or more semiconductor packages can be stacked one on top of another.

### SUMMARY OF THE INVENTION

In one aspect, the invention features a method of manufacturing an integrated circuit package including providing a lead frame without a die attachment pad, said lead frame having a ridge portion protruding from a base portion, said ridge portion with an upper surface and defining an upper portion of a cavity, said base portion comprising a lead and a lower surface, attaching an adhesive strip to at least the lower surface of the base portion to seal a bottom portion of the cavity, encapsulating the cavity such that at least a portion of the upper surface of the ridge portion of the lead frame and at least a portion of the lower surface of the base portion are exposed, and removing the adhesive strip.

In another aspect, the invention features a method of manufacturing a integrated circuit package including providing a lead frame having a ridge portion protruding from a base portion, the ridge portion comprising an upper surface and defining an upper portion of a cavity, the base portion having a lower surface and consisting essentially of a peripheral frame section and a plurality of inwardly projecting leads in a ring-like configuration, attaching an adhesive strip to at least the lower surface of said base portion to seal a bottom portion of said cavity, encapsulating the cavity such that at least a portion of the upper surface of the ridge portion of the lead frame and at least a portion of the lower surface of the base portion are exposed, and removing the adhesive strip.

In yet another aspect, the invention features a method of manufacturing an integrated circuit package including providing a substantially annular lead frame having a body and an internally projecting ring-like configuration of leads, the leads being the innermost portion of the lead frame, the body having a ridge portion protruding from a base portion, the ridge portion having an upper surface and defining an upper portion of a cavity, attaching an adhesive strip to at least the lower surface of the base portion to seal a bottom portion of the cavity, encapsulating the cavity such that at least a portion of the upper surface of the ridge portion of the lead frame and at least a portion of the lower surface of the base portion are exposed, and removing the adhesive strip.

In a further aspect, the invention features a method of manufacturing an integrated circuit package including providing a matrix of lead frames arranged in a strip, each lead frame without a die attachment pad, each of said lead frames having a ridge portion protruding from a base portion, the ridge portion having an upper surface and defining an upper portion of a cavity, the base portion having a lead and a lower surface, attaching an adhesive strip to at least a bottom surface of the strip to seal a bottom portion of at least one of the cavities, encapsulating at least one cavity such that at least a portion of the upper surface of the ridge portion of at least one of the lead frames and at least a portion of the lower surface of at least one of the lead frames is exposed, and removing the adhesive strip.

### BRIEF DESCRIPTION OF THE DRAWINGS

The foregoing features, methods and other aspects of the invention are explained in the following description taken in connection with the accompanying drawings, wherein:

FIG. 1 is a simplified cross-sectional view of an integrated circuit package 10 manufactured according to one embodiment of the present invention;

FIG. 2 is a simplified cross-sectional view of an integrated circuit package 20 manufactured according to another embodiment of the invention;

FIG. 3 shows a strip 30, including six sections 31-1 to 31-6, which may be used in a method of manufacture according to an embodiment of the present invention.

FIG. 4 shows a 3×3 array 40 of lead frames 100-1 to 100-9, before being singulated, which may be provided in one or more of the sections 31 -1 to 31-6 of the strip 30.

FIG. 5 shows a flowchart describing major steps performed in methods of manufacture according to embodiments of the present invention.

FIGS. 6a-6h show simplified cross-sectional views of certain steps of one method of manufacture according to an embodiment of the present invention.

### DETAILED DESCRIPTION OF PREFERRED EMBODIMENTS

Various embodiments of the methods of manufacturing integrated circuit packages according to embodiments of the present invention will now be described with reference to the drawings.

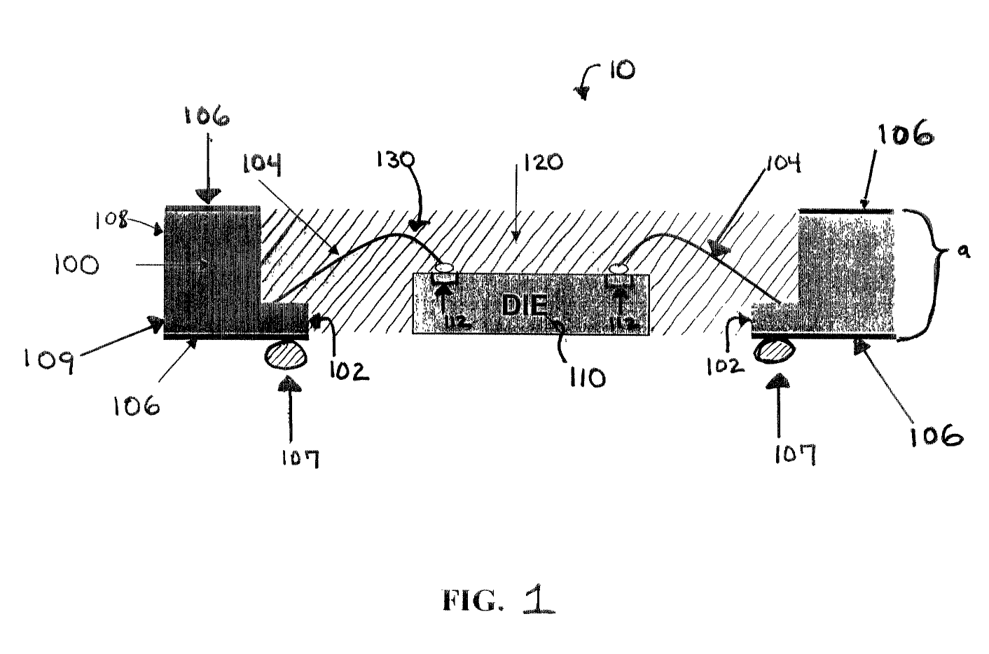

FIG. 1 shows a cross-sectional view along one dimension of an integrated circuit package 10 manufactured according to one embodiment of the present invention. This cross-sectional view shows certain components of the package 10 displayed in their respective positions relative to one another. The integrated circuit package 10 depicted in FIG. 1 generally includes a lead frame 100, a semiconductor die 110 and an encapsulant 120. In this embodiment, the package 10 measures about 0.5 mm thick (shown as dimension “a” in FIG. 1).

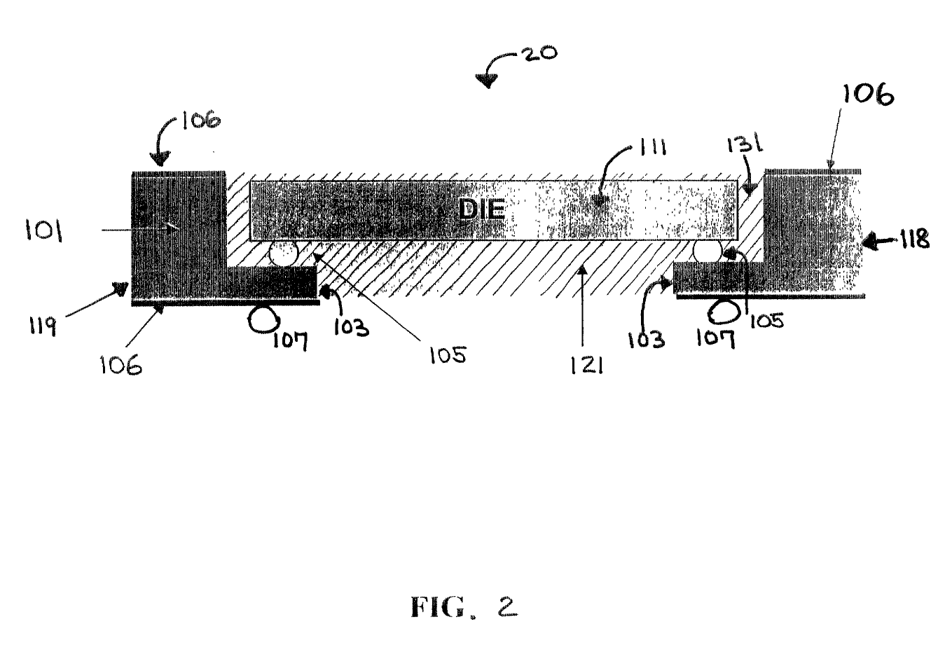

FIG. 2 shows a cross-sectional view along one dimension of another integrated circuit package 20 manufactured according to another embodiment of the present invention. The integrated circuit package 20 depicted in FIG. 2 generally includes a lead frame 101, a semiconductor die 111 and an encapsulant 121.

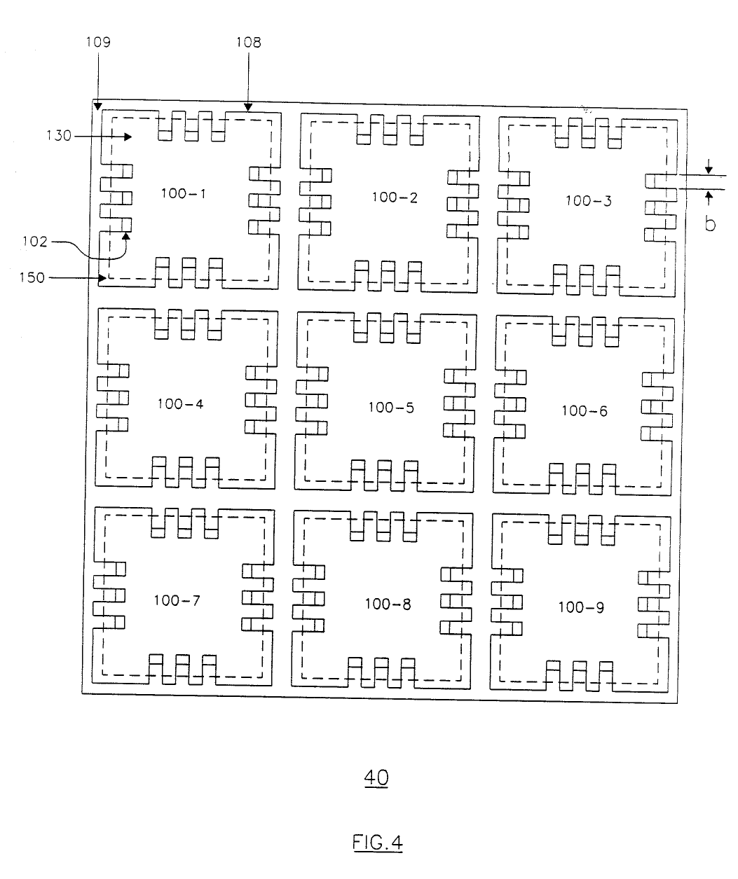

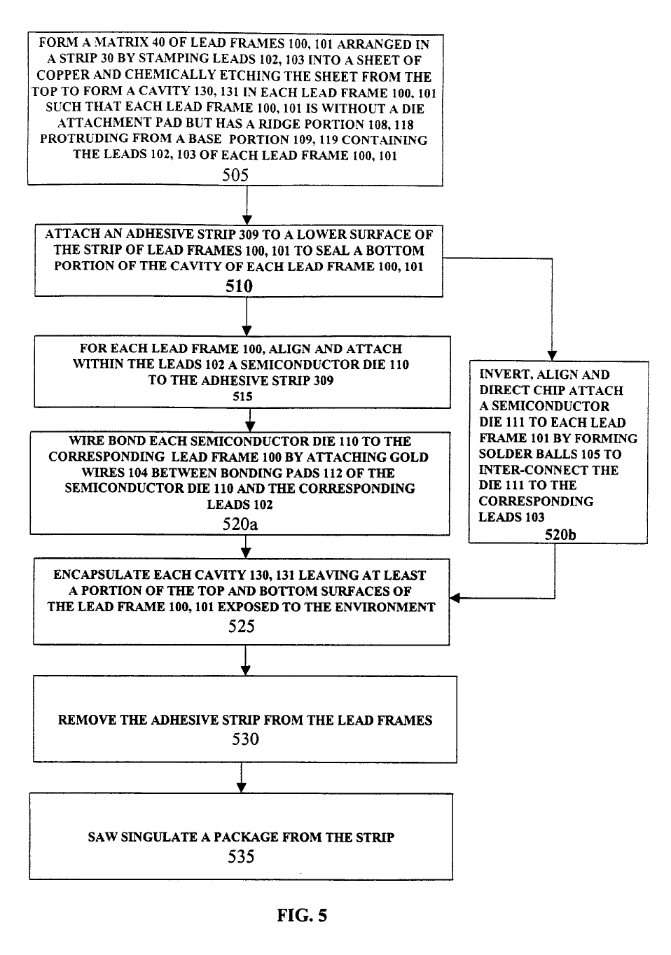

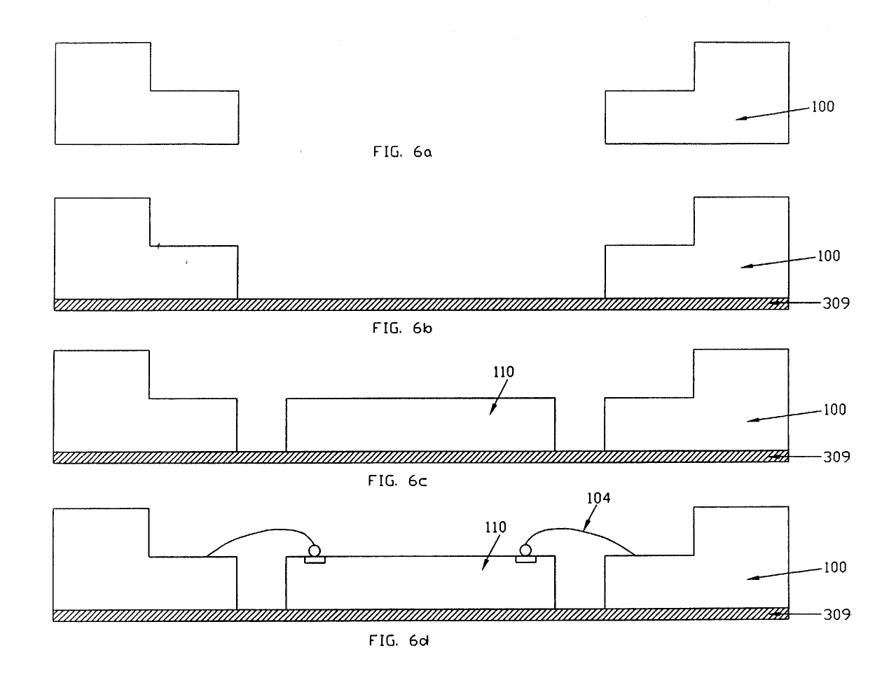

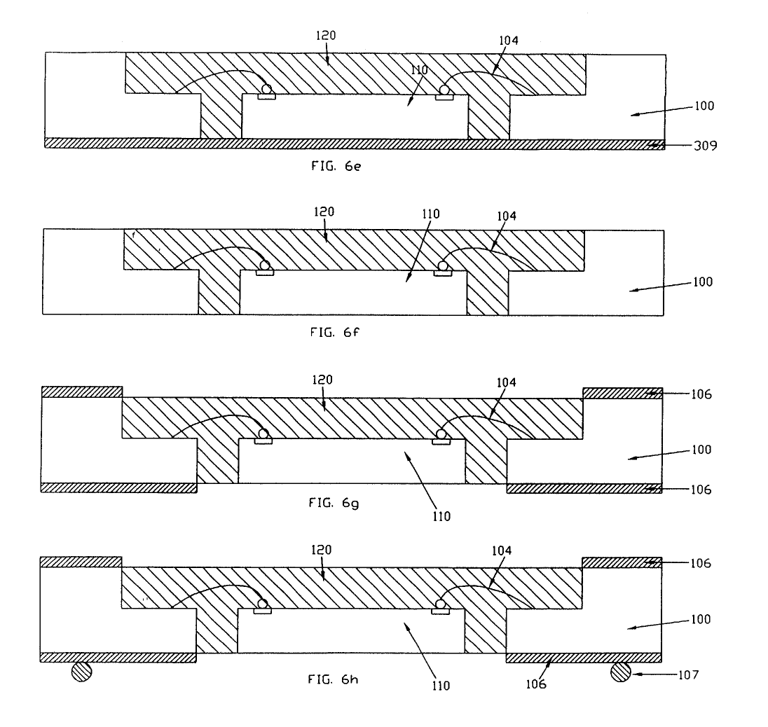

Each of the foregoing will now be described in greater detail, followed by certain manufacturing or assembly steps (shown in FIGS. 5 and 6a-6h) associated with them.

In the integrated circuit package shown in FIG. 1, the lead frame 100 has leads 102 onto which a semiconductor die 110 can be interconnected using, for example, a wire bonding technique. In this embodiment, spacing between adjacent leads 102 may be approximately 0.25 mm, and each lead 102 may be about 0.25 mm wide (shown as dimension “b” in FIG. 4). FIG. 1 shows a semiconductor die 110 connected to the leads 102 of the lead frame 100 via a gold thermo-sonic wire bonding technique. In such an integrated circuit package, conductive gold wires 104 interconnect the semiconductor die 110 to the leads 102 of the lead frame 100. These wires 104 are each bonded to both the bonding pads 112 of the semiconductor die 110 at one end, and the corresponding lead 102 at the other end. The bonding pads 112 provide locations at which the semiconductor die 110 may receive power and/or input signals, as well as transmit output signals.

FIG. 2 shows an integrated circuit package manufactured according to another embodiment of the present invention, wherein the semiconductor die 111 is interconnected to the leads 103 of the lead frame 101 by a direct chip attachment technique. In the integrated circuit package shown in FIG. 2, the semiconductor die 111 is connected to the leads 103 via direct chip attachment using solder balls 105.

The wires 104 and solder balls 105 are electrical attach members that electrically connect a semiconductor die 110, 111 to leads 102, 103 of a package 10, 20 such that the semiconductor die 110, 111 may receive power, input signals and/or output signals.

The lead frames 100, 101 of the integrated circuit packages 10, 20 shown in FIGS. 1 and 2, respectively, are made of an electrically conductive material such as, e.g., copper. However, the lead frame 100, 101 may be made of other metals, electrically conductive materials, or electrically conductive compounds in other embodiments of the present invention. The lead frame 100, 101 provides, at least in part, interconnections between the power, input and/or output terminals of the semiconductor die 110, 111 and any external terminals that may be provided on the integrated circuit package 10, 20. In one embodiment, portions of the upper and lower surfaces of the lead frame 100, 101 are plated with solder or pure tin (Sn) 106. This solder or pure tin plating 106 provides an interface surface for mechanical, electrical or both types of connection of the integrated circuit package 10, 20 to an external device (not shown). Alternatively, the lead frame 100, 101 may be pre-plated with palladium to avoid silver migration.

As shown in FIGS. 1 and 2, the external terminals of the packages 10, 20 may include an array of conductive members such as, e.g., solder balls 107. Those solder balls 107 may be attached to corresponding leads 102, 103 using a reflow soldering process. The solder balls 107 may function as electrical extensions of the leads 102, 103, and may be capable of providing power, signal inputs and signal outputs to and from the semiconductor die 110, 111. The solder balls 107 can be made of a variety of materials including lead (Pb) free solder. Such a configuration may be referred to as a type of ball grid array. Absent the solder balls 107, such a configuration may be referred to as a type of land grid array.

According to embodiments of the present invention, each semiconductor die 110, 111 and lead frame 100, 101 are encapsulated to form an integrated circuit package 10, 20. The encapsulant 120, 121 may be, for example, an epoxy based material applied by, for example, a liquid encapsulation process or a transfer molding encapsulation process.

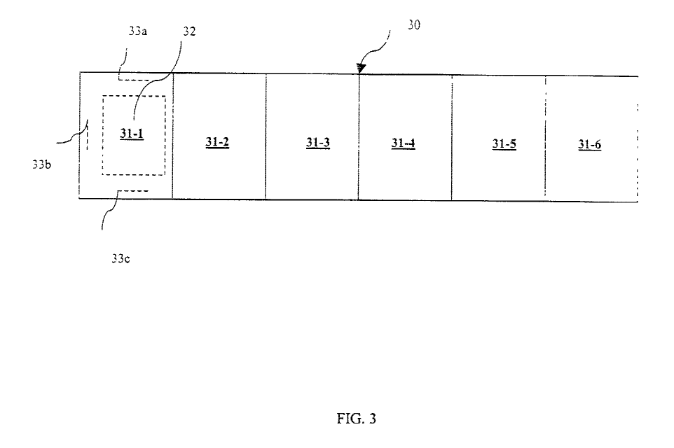

FIG. 3 shows a strip 30 including six sections 31-1 to 31-6 which can be used in a method of manufacture according to an embodiment of the present invention. Using such a strip 30 allows a particular assembly process to be carried out in conventional automated assembly equipment and molds if appropriate for a particular application. Several lead frames 100, 101 may be produced in the form of, or otherwise assembled into, the strip 30 shown in FIG. 3. Each of sections 31-1 to 31-6 may include a frame area 32 in which lead frames such as the lead frames 100, 101 described above can be formed using, for example, a chemical etching process, a stamping process, a combination of these two types of processes and/or other processes.

As shown in FIG. 4, several lead frames may also be configured in a matrix array 40 to accommodate high-density package manufacturing. For example, the strip 30 shown in FIG. 3 may contain six substantially identical sections 31-1 to 31-6, each of which may contain a 3×3 matrix array 40 similar to that shown in FIG. 4, which is shown accommodating nine lead frames. A matrix array 40 like the one shown in FIG. 4 may be formed in the frame area 32 of each section 31 of the strip 30. Thus, in this configuration, fifty-four lead frames may be formed in each strip 30. Other configurations of either the strip 30, the matrix array 40, or both, will produce other volumes of lead frames. The periphery of the frame area 32 may contain alignment targets, tooling through-holes and other features (labeled, collectively, by reference numerals 33a-33c) for use in automated assembly equipment.

Referring again to FIG. 1, an intermediate preassembly of an integrated circuit package manufactured according to an embodiment of the present invention includes a lead frame 100 with a ridge portion 108 and a base portion 109. As shown in FIG. 4, this ridge portion 108 may be formed around a periphery of the lead frame 100 and may have an approximately annular shape when viewed from an upper surface of the integrated circuit package 10. Also as shown in FIG. 4, this ridge portion 108 may be continuous, although it is not required that the ridge portion be continuous.

As shown in FIGS. 1 and 4, the ridge portion 108 of the lead frame 100 may be integrally formed with and protrude upward from the base portion 109 of the lead frame 100 in a substantially perpendicular fashion, thereby defining a portion of a cavity 130. The cavity 130 may include the entire inner area of the lead frame 100, and may be bounded on the sides by the ridge portion 108 and base portion 109 (including the leads 102), on the top by the ridge portion 108, and on the bottom by the base portion 109 and leads 102. As described above, some of the ridge portion 108 and base portion 109 of the lead frame 100 of one integrated circuit package provide a means for electrically coupling and mechanically attaching a second integrated circuit package with the present package 10. Also as described above, the ridge portion 108 may form continuous sides of a cavity 130 to prevent most or all of the encapsulant 120 from escaping the cavity 130 through its sides during manufacture of the package.

In the integrated circuit packages shown in FIGS. 1, 2 and 4, the base portion 109 contains integrally formed leads 102 that project inward and toward the location of the semiconductor die 110 to form a ring 150 of leads 102. In the integrated circuit package depicted in FIG. 4, the lead frame 100 may also include a marker 160 provided at the upper left-hand corner of the package to provide an identification of a particular reference pin (e.g., pin number 1) of the semiconductor die 110, or to help identify the orientation of the package, particularly after manufacture has been completed.

The integrated circuit package 20 shown in FIG. 2 also includes a lead frame 101 with a ridge portion 118 and a base portion 119. Embodiments of the methods of manufacturing integrated circuit packages according to the present invention will now be described with reference to the drawings, in particular, FIGS. 5 and 6a-6h.

As represented in step 505 shown in FIG. 5, a lead frame 100, 101 may be formed into the configuration shown in the figures (e.g., FIGS. 1, 2 and 4) by a number of different processes including a chemical process (e.g., top-down etching), a mechanical process (e.g., metal stamping), or a combination of these and/or other processes. For example, a lead frame 100, 101 may be stamped from a sheet of copper to create the base portion 109, 119 and the leads 102, 103, then half-etched from the top to create the ridge portion 108, 118. In such an example method of manufacture, a lead frame 100, 101 may be stamped and etched while it is a part of a matrix array 40 of lead frames. In another method of manufacturing embodiments of the package of the present invention, a stamping process alone may also be used to create the base portion 109, 119, the leads 102, 103 and the ridge portion 108, 118.

As depicted in step 510 of FIG. 5 (and FIGS. 6a-6b), after one or more lead frames 100, 101 are formed, a pre-formed adhesive strip 309 may be attached to a bottom surface of the lead frame or frames 100, 101. In one embodiment, the adhesive strip 309 is made of sufficiently dense material to prevent the encapsulant 120, 121 material from passing through it. This adhesive strip 309 is also capable of creating a bond of sufficient strength with the lead frame 100, 101 to prevent the encapsulant 120, 121 material from passing into or through the interface between the adhesive strip 309 and the lead frame 100, 101. In this way, the adhesive strip 309 seals the bottom of the cavity 130, 131.

In one example manufacturing process, a semiconductor die 110 as shown in FIG. 1 is then aligned within the ring 150 of leads 102 of the lead frame 100 shown in FIG. 4, and is mounted on the adhesive strip 309 (depicted in FIG. 6c). In the embodiment shown in FIG. 1, the semiconductor die 110 may be aligned within the inner surfaces of the leads 102, but not in direct contact (other than by the wires 104) with any portion of the lead frame 100.

In an embodiment using a wire-bonding technique, a semiconductor die 110 may be first aligned and attached (step 515) to the adhesive strip 309, and then wire-bonded (step 520a) to the leads 102 using conventional automated bonding equipment (depicted in FIGS. 6c and 6d). To create the package 10 shown in FIG. 1, gold wires 104 may be used in this wire-bonding operation. Wire-bonds electrically couple each bonding pad 112 on a semiconductor die 110 to a corresponding one of the leads 102.

As one type of alternative process to wire bonding, an embodiment including direct chip attachment technique may also be used. The assembly process for a package 20 having a direct chip attachment may follow the assembly process described above. However, rather than first attaching the semiconductor die 110 to the adhesive strip 309 and then wire-bonding the semiconductor die 110 to the leads 102 as described above, the semiconductor chip 111 is inverted, aligned and then attached directly (step 520b) to the leads 103 by solder balls 105.

Following attachment of the semiconductor die 110, 111, the lead frame 100, 101 with the adhesive strip 309 and semiconductor die 110, 111 attached thereto may be encapsulated. In one assembly method, the cavity 130, 131 formed by the ridge portion 108, 118 of the lead frame 100, 101 is filled with encapsulant 120, 121 material during an encapsulation (depicted at step 525 of FIG. 5 and in FIG. 6e). To create the packages 10, 20 shown in FIGS. 1 and 2, the top plate of a mold used for encapsulation is substantially flat in the appropriate areas. The encapsulant 120, 121 may be an epoxy based material applied by, for example, either a liquid encapsulation process or a transfer molding encapsulation process. During molding, the adhesive strip 309 prevents some or all of the bottom surfaces of the semiconductor dies 110, 111 and the leads 102, 103 from being covered with encapsulant material 120, 121. In this way, the semiconductor die 110, 111 and its attachment means (e.g., gold wires 104 or solder balls 105), as well as the cavity 130, 131 created at least in part by the ridge portion 108, 118 of the lead frame 100, 101, may be encapsulated to form an intermediate preassembly of an integrated circuit package 10, 20. Upon completion of this assembly step of a particular assembly embodiment, at least a portion of the top surface of the ridge portion 108, 118 of the lead frame 100, 101 remains exposed to allow electrical connection to a printed circuit board (not shown), another semiconductor die and/or another integrated circuit package.

After the encapsulant 120, 121 material has cured or otherwise attained a sufficiently solid material state, the adhesive strip 309 is removed and discarded (depicted at step 530 of FIG. 5 and in FIG. 6f).

As shown in FIG. 6g, the lead frame 100 may be solder or pure tin plated 106 to facilitate a subsequent board-attach step. Solder or pure tin plating 106 may not be necessary, however, if the strip 30 was pre-plated with palladium. Solder balls 107 may then be attached to the leads 102, 103 of each lead frame 100, 101 using, for example, a reflow soldering process (depicted in FIG. 6h). Solder balls 107 attached to the exposed portions of the leads 102, 103 may provide a clearance when the package 10, 20 is mounted on a printed circuit board. Such clearance may facilitate cleaning (e.g., cleaning of solder flux).

In one embodiment of the method of manufacture according to the present invention, after the encapsulation and ball attachment assembly steps, the intermediate preassembly of the integrated circuit packages 10, 20 may be singulated into individual units using a saw singulation or punching technique (step 535). During saw singulation, the strip 30 may be mounted to a wafer saw ring by an adhesive tape and saw-singulated using a conventional wafer saw. Singulation can be guided by alignment targets and other features (labeled as reference numbers 33a-33c) formed on the lower surface along the periphery of strip 30 (for example, etched or stamped into the lead frame). Such targets or features may be incorporated into the strip 30 during its fabrication, and may help to maintain accurate size tolerances of each integrated circuit package produced in this way. In one example method, the underside of the strip 30 faces upward during a saw singulation process. Once singulated, an individual package 10, 20 may be ready for mounting onto a printed circuit board or other device. In FIG. 4, integrated circuit packages are represented as the portions of the matrix 40 within the dotted lines.

The underside of strip 30 may be deflashed to remove any molding compound residues from the exposed surfaces of the lead frames, so as to allow the leads and the ridge portion of the lead frames to serve as solder pads for attachment to a printed circuit board or other device at a subsequent time.

Although specific embodiments and example methods of the present invention have been shown and described, it is to be understood that there are other embodiments and examples which are equivalent to the explicitly described embodiments and examples. Accordingly, the invention is not to be limited by the specific illustrated embodiments and examples, but only by the scope of the appended claims.

What is claimed is:

1. A method of manufacturing an integrated circuit package, comprising:
providing a lead frame without a die attachment pad, said lead frame comprising a ridge portion protruding from a base portion, said ridge portion comprising an upper surface and defining an upper portion of a cavity, said base portion comprising a lead and a lower surface;
attaching an adhesive strip to at least said lower surface of said base portion to seal a bottom portion of said cavity;
encapsulating said cavity such that at least a portion of said upper surface of said ridge portion of said lead frame and at least a portion of said lower surface of said base portion are exposed; and
removing said adhesive strip.

2. The method of claim 1, further comprising, prior to encapsulating said cavity, attaching an electrical attachment member between a semiconductor die and said lead frame.

3. The method of claim 2, wherein said electrical attachment member comprises a wire.

4. The method of claim 2, wherein said electrical attachment member comprises a direct chip attachment member.

5. The method of claim 1, further comprising singulating said integrated circuit package.

6. The method of claim 5, said singulating comprising a saw singulation.

7. The method of claim 2, further comprising attaching said semiconductor die to said adhesive strip prior to attaching said electrical attachment member.

8. The method of claim 1, further comprising plating at least a portion of said lower surface of said base portion.

9. The method of claim 1, further comprising plating at least a portion of said upper surface of said ridge portion.

10. The method of claim 9, said plating comprising essentially pure tin.

11. The method of claim 1, said lead frame comprising a substantially continuous ridge.

12. A method of manufacturing an integrated circuit package, comprising:
providing a lead frame comprising a ridge portion protruding from a base portion, said ridge portion comprising an upper surface and defining an upper portion of a cavity, said base portion having a lower surface and consisting essentially of a peripheral frame section and a plurality of inwardly projecting leads in a ring-like configuration;
attaching an adhesive strip to at least said lower surface of said base portion to seal a bottom portion of said cavity;
encapsulating said cavity such that at least a portion of said upper surface of said ridge portion of said lead frame and at least a portion of said lower surface of said base portion are exposed; and
removing said adhesive strip.

13. The method of claim 12, further comprising singulating said integrated circuit package.

14. The method of claim 13, said singulating comprising a saw singulation.

15. A method of manufacturing an integrated circuit package, comprising:
providing a substantially annular lead frame comprising a body and an internally projecting ring-like configuration of leads, said leads being the innermost portion of said lead frame, said body comprising a ridge portion protruding from a base portion, said ridge portion comprising an upper surface and defining an upper portion of a cavity;
attaching an adhesive strip to at least said lower surface of said base portion to seal a bottom portion of said cavity;
encapsulating said cavity such that at least a portion of said upper surface of said ridge portion of said lead frame and at least a portion of said lower surface of said base portion are exposed; and
removing said adhesive strip.

16. The method of claim 15, further comprising singulating said integrated circuit package.

17. The method of claim 16, said singulating comprising a saw singulation.

18. A method of manufacturing an integrated circuit package, comprising:
providing a matrix of lead frames arranged in a strip, each lead frame without a die attachment pad, each of said lead frames comprising a ridge portion protruding from a base portion, said ridge portion comprising an upper surface and defining an upper portion of a cavity, said base portion comprising a lead and a lower surface;
attaching an adhesive strip to at least a bottom surface of said strip to seal a bottom portion of at least one of said cavities;
encapsulating at least one said cavity such that at least a portion of said upper surface of said ridge portion of at least one of said lead frames and at least a portion of said lower surface of at least one of said lead frames is exposed; and
removing said adhesive strip.

19. The method of claim 18, further comprising singulating said integrated circuit package from said strip.

20. The method of claim 19, said singulating comprising a saw singulation.
